(19) United States
(12) Patent Application Publication
(10) Pub. No.: US 2014/0117418 A1
(43) Pub. Date: May 1, 2014

(54) THREE-DIMENSIONAL SILICON-BASED TRANSISTOR COMPRISING A HIGH-MOBILITY CHANNEL FORMED BY NON-MASKED EPITAXY

(71) Applicant: GLOBALFOUNDRIES INC., Grand Cayman (KY)

(72) Inventors: Stefan Flachowsky, Dresden (DE); Ralf Illgen, Dresden (DE); Jan Hoentschel, Dresden (DE)

(73) Assignee: GLOBALFOUNDRIES INC., Grand Cayman (KY)

(21) Appl. No.: 13/663,941

(22) Filed: Oct. 30, 2012

(51) Int. Cl. H01L 21/336; H01L 29/78

(52) U.S. Cl. 257/288; 438/283; 257/E29.255; 257/E21.421

(57) ABSTRACT

Three-dimensional transistors may be formed on the basis of high mobility semiconductor materials, which may be provided locally restricted in the channel region by selective epitaxial growth processes without using a mask material for laterally confining the growing of the high mobility semiconductor material. That is, by controlling process parameters of the selective epitaxial growth process, the cross-sectional shape may be adjusted without requiring a mask material, thereby reducing overall process complexity and providing an additional degree of freedom for adjusting the transistor characteristics in terms of threshold voltage, drive current and electrostatic control of the channel region.

### BACKGROUND OF THE INVENTION

1. Field of the Invention

Generally, the present disclosure relates to highly sophisticated integrated circuits including transistors having three-dimensional channel architecture (FinFET) including a semiconductor material having superior mobility compared to a semiconductor base material, such as silicon.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout, wherein field effect transistors represent one important type of circuit element that substantially determines performance of the integrated circuits. Generally, a plurality of process technologies are currently practiced, wherein, for many types of complex circuitry, including field effect transistors, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a planar transistor architecture, the distance between the source and drain regions, which is also referred to as channel length.

Presently, the vast majority of integrated circuits are based on silicon due to substantially unlimited availability, the well-understood characteristics of silicon and related materials and processes and the experience gathered during the last 50 years. Therefore, silicon will likely remain a dominant base material for forming complex integrated circuits designed for mass products. One reason for the dominant importance of silicon in fabricating semiconductor devices has been the superior characteristics of a silicon/silicon dioxide interface that allows reliable electrical insulation of different regions from each other. The silicon/silicon dioxide interface is stable at high temperatures and, thus, allows the performance of subsequent high temperature processes, as are required, for example, for anneal cycles to activate dopants and to cure crystal damage without sacrificing the electrical characteristics of the interface.

For the reasons pointed out above, in field effect transistors, silicon dioxide is preferably used as a gate insulation layer that separates the gate electrode, frequently comprised of polysilicon or metal-containing materials, from the silicon channel region. In steadily improving device performance of field effect transistors, the length of the channel region has been continuously reduced to improve switching speed and drive current capability. Since the transistor performance is controlled by the voltage supplied to the gate electrode to invert the surface of the channel region to a sufficiently high charge density for providing the desired drive current for a given supply voltage, a certain degree of capacitive coupling, provided by the capacitor formed by the gate electrode, the channel region and the silicon dioxide disposed therebetween, has to be maintained. It turns out that decreasing the channel length for a planar transistor configuration requires an increased capacitive coupling to avoid the so-called short channel behavior during transistor operation. The short channel behavior may lead to an increased leakage current and generally to reduced controllability of the current flow. Aggressively scaled planar transistor devices with a relatively low supply voltage and thus reduced threshold voltage may suffer from an exponential increase of the leakage current, while also requiring enhanced capacitive coupling of the gate electrode to the channel region. Thus, the thickness of the silicon dioxide layer has to be correspondingly reduced to provide the required capacitance between the gate and the channel region, thereby contributing to relatively high leakage currents that may not be compatible with requirements for performance driven circuits.

For this reason, superior gate electrode structures have been developed in which new gate dielectric materials may be implemented, possibly in combination with additional electrode materials, in order to provide superior capacitive coupling between the gate electrode and the channel region, while at the same time maintaining the resulting leakage currents at a low level. To this end, so-called high-k dielectric materials may frequently be used, which are to be understood as dielectric materials having a dielectric constant of 10.0 and higher. For example, a plurality of metal oxides or silicates may be used, possibly in combination with conventional very thin dielectric materials, in order to obtain sophisticated high-k metal gate electrode structures. For example, in some well-established approaches, the gate electrode structures of planar transistors may be formed on the basis of well-established concepts, i.e., using conventional gate dielectrics and polysilicon material, wherein the sophisticated material systems may then be incorporated in a very late manufacturing stage, i.e., prior to forming any metallization systems and after completing the basic transistor configuration by replacing the polysilicon material with the high-k dielectric material and appropriate gate electrode materials. Consequently, in any such replacement gate approaches, well-established process techniques and materials may be used for forming the basic transistor configurations, while, in a late manufacturing stage, i.e., after performing any high temperature processes, the sophisticated gate materials may be incorporated.

In view of further device scaling based on well-established materials, new transistor configurations have been proposed in which a “three-dimensional” architecture is provided in an attempt to obtain a desired channel width, while at the same time superior controllability of the current flow through the channel region is preserved. To this end, so-called FinFETs have been proposed in which a thin sliver or fin of silicon is formed in a thin active layer of a silicon-on-insulator (SOI) substrate, wherein, on both sidewalls and, if desired, on a top surface, a gate dielectric material and a gate electrode material are provided, thereby realizing a multiple gate transistor whose channel region may be fully depleted. Typically, in sophisticated applications, the width of the silicon fins is on the order of magnitude of 10-40 nm and the height thereof is on the order of magnitude of 30-90 nm.

In some conventional approaches for forming FinFETs, the fins are formed as elongated device features, followed by the deposition of the gate electrode materials, possibly in combination with any spacers, and thereafter the end portions of the fins may be “merged” by epitaxially growing a silicon material, which may result in complex manufacturing processes, thereby also possibly increasing the overall external resistance of the resulting drain and source regions.

In further attempts to provide FinFETs on the basis of a bulk configuration, it has been proposed to form semiconductor fins in a bulk substrate on the basis of a self-aligned process strategy in which a gate opening is defined by an appropriate etch mask formed above the semiconductor material. In a further step, the opening is patterned by complex lithography techniques so as to obtain a further mask, which may define the lateral position and size of the fins, which may subsequently be formed on the basis of complex patterning strategies. Thereafter, an appropriate dielectric material, such as silicon dioxide, may be filled into the resulting structure in order to appropriately adjust the electrical effective height of the previously etched fins.

In recent developments, the three-dimensional architecture of transistors has been combined with other performance increasing mechanisms, such as the provision of sophisticated high-k metal gate electrode structures, strain-inducing mechanisms and the like. Generally, the three-dimensional configuration of transistors may provide superior controllability of the channel region, since the gate voltage and thus the corresponding electric field may be applied on the basis of two or even three surface areas of the semiconductor fin, thereby efficiently enabling a total depletion of the channel region, as discussed above. In order to further enhance overall performance of three-dimensional transistors, it has been proposed to transfer certain technologies, frequently used in planar transistor designs, into the three-dimensional architecture in order to take advantage of the inherent higher charge carrier mobility of certain semiconductor materials, such as silicon/germanium, germanium, III-V semiconductor alloys and the like. It appears, however, that providing a semiconductor base material other than silicon material may require enormous efforts with respect to etch strategies, cleaning recipes, deposition processes and the like, thereby rendering this concept as effectively impracticable in current high volume production sites.

For this reason, it has been proposed to use high-mobility semiconductor materials in critical transistor areas only, that is, in the channel region, while nevertheless preserving a high degree of compatibility with well-established silicon technologies. In this manner, the advantages of the intrinsic high charge carrier mobility of certain semiconductor materials may be efficiently transferred into MOS and CMOS techniques, without requiring undue process modifications of the well-established silicon process technology. For example, a high mobility semiconductor material may be formed on the basis of selective epitaxial growth techniques in a very spatially restricted manner, while the remaining components may be provided on the basis of the semiconductor base material, such as silicon. For example, in conventional process strategies, the previously formed silicon-based semiconductor fin, or at least a central portion thereof, is laterally embedded in a disposable shaper material or mask material, which thus reproduces the lateral dimensions of the previously formed silicon fin. Thereafter, the silicon material confined by the mask material is removed to a desired depth, thereby forming a silicon surface that may then be used as a growth surface for the selective deposition of the desired high mobility semiconductor material. Consequently, during the selective epitaxial growth process, the mask material laterally confines the desired high mobility semiconductor material so that the newly grown high mobility certain portion has the same lateral dimensions as the initially grown silicon thin. Thereafter, the mask material is removed and the processing is continued in accordance with the basic recess strategy. For example, the above-described process strategy is frequently combined with the provision of a sophisticated high-k metal gate electrode structure that is provided on the basis of a so-called replacement gate approach. In this manufacturing strategy, a placeholder gate electrode structure is provided so as to cover the channel region of the silicon-based fins in order to basically complete the transistor, such as drain and source regions. Thereafter, the placeholder gate electrode structure is removed, thereby also exposing the channel area of the silicon fins, which may thus be processed as described above in order to implement the high mobility channel regions in the three-dimensional transistor architecture. Next, the actual gate materials are formed in accordance with well-established process strategies.

Consequently, the incorporation of a high mobility semiconductor material into the channel region of sophisticated three-dimensional transistors is a very promising approach for enhancing transistor performance while still preserving a high degree of compatibility with well-established silicon technology. On the other hand, additional deposition and etch processes are required for providing the mask material, which may contribute to further process complexity and reduced flexibility in appropriately defining transistor characteristics of three-dimensional transistors.

In view of the situation described above, the present disclosure relates to semiconductor devices and manufacturing techniques in which FinFETs, or generally three-dimensional transistors, may be formed on the basis of a high mobility channel region, while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques and semiconductor devices in which FinFET devices, or generally three-dimensional transistors, may be formed on the basis of a channel semiconductor material that differs from a semiconductor base material that is used for forming other semiconductor-based components of the semiconductor device. To this end, selective epitaxial growth techniques are applied, in which the lateral growth is controlled without using a mask material, thereby avoiding additional deposition and etch processes and also providing superior flexibility in adjusting the cross-sectional shape of the channel regions, that is, the cross-section that is perpendicular to the current flow direction within the channel region. For example, it is well known that process parameters and precursor materials and other components in a selective epitaxial deposition atmosphere may be selected such that the growth of the semiconductor material depends on the crystal orientation of a surface that acts as a “template” surface. For example, different crystal planes, when acting as a growth surface, may require different activation energy and thus a different set of process parameters, such as pressure, temperature, gas flow rates and the like, in order to initiate the epitaxial growth. Consequently, upon growing a desired semiconductor material on a bottom face, i.e., a template surface, of a semiconductor base material, by controlling the process parameters of the epitaxial deposition process, a self-limiting lateral growth may be achieved, thereby enabling a controlled adjustment of the cross-sectional shape of the resulting semiconductor material. For example, if the growth parameters are selected such that significant material deposition is achieved on the initial template surface having a specific surface orientation, while a significant material deposition on any other surface orientation is suppressed, the lateral dimensions of the template surface are substantially replicated during the entire epitaxial growth, thereby also preserving the lateral dimensions of a semiconductor fin that has previously been removed in order to provide the template surface.

In other cases, process parameters may be selected such that a certain degree of growth may also be allowed in other crystal orientations, however, with different growth rates, thereby providing the possibility of adjusting a desired cross-sectional shape. Since the process parameters may be dynamically changed during the growth process, the lateral growth rate and, thus, the finally obtained cross-sectional shape may be specifically adapted in view of the finally required transistor characteristics. For example, the cross-sectional shape, such as rectangular, hexagonal, oval and the like, may be adjusted in order to enhance channel controllability, drive current capability, threshold voltage and the like.

Consequently, by avoiding the presence of the mask material during the selective epitaxial growth process upon forming a channel region of a desired semiconductor material, not only a significant reduction of process complexity may be achieved, but also additional design flexibility is obtained by using a non-mask epitaxial growth process with a process-controlled lateral growth. Furthermore, the above-described process strategy may be applied in combination with any desired device configuration, such as bulk architecture or SOI architecture, sophisticated high-k metal gate electrode structures that may be provided, for instance, on the basis of replacement gate approaches, self-aligned strategies, in which the initial semiconductor fins, which may also be referred to as “disposable” semiconductor fins, may be formed on the basis of self-aligned process techniques with respect to drain and source regions, wherein the disposable semiconductor fins may be provided in an early manufacturing stage or in a late manufacturing stage, and the like.

One illustrative method disclosed herein comprises forming a fin from a semiconductor base material in an active region of a semiconductor device, wherein the fin has a first end portion terminating in a drain region of the active region, and has a second end portion terminating in a source region. The method further comprises removing at least a portion of the fin so as to provide a crystalline template surface, which has lateral dimensions determined by the fin. Additionally the method comprises forming a channel region on the crystalline template surface so as to connect to the drain and source regions by forming a semiconductor material in a selective epitaxial growth without restricting a lateral growth of the semiconductor material by a mask material.

A further illustrative method disclosed herein relates to forming a semiconductor device. The method comprises forming a crystalline template surface in a semiconductor base material, wherein the crystalline template surface is located laterally between a drain region and a source region. Furthermore, the method comprises forming a channel region on the crystalline template surface by growing a semiconductor material while controlling a lateral growth rate by using a crystallographically anisotropic deposition recipe. The method additionally comprises forming a gate dielectric material and an electrode material of a gate electrode structure on at least a portion of the channel region.

One illustrative semiconductor device disclosed herein comprises a drain region and a source region formed in a semiconductor base material of the semiconductor device, wherein the drain region and the source region have a drain and source width along a width direction. The semiconductor device further comprises a channel region formed from a semiconductor material other than the semiconductor base material and extending between the drain region and the source region, wherein the channel region has a width along the width direction that is less than the drain and source width. Furthermore, the width of the channel region varies along a height direction. Moreover, the semiconductor device comprises a gate electrode structure formed on sidewalls of the channel region and above a top surface of the channel region.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a perspective view of a three-dimensional transistor or FinFET, according to illustrative embodiments;

FIG. 1b schematically illustrates a top view of the three-dimensional transistor with a self-aligned semiconductor fin in an early manufacturing stage, according to illustrative embodiments;

FIG. 1 c schematically illustrates a cross-sectional view along a transistor width direction, according to the section A-A of FIG. 1b, according to illustrative embodiments;

FIG. 1 d schematically illustrates a cross-sectional view of the transistor along section B-B in a further advanced manufacturing stage, according to illustrative embodiments;

FIG. 1e schematically illustrates a cross-sectional view of the transistor along the section A-A in a further advanced manufacturing stage, according to illustrative embodiments;

FIGS. 1f, 1g and 1h schematically illustrate a top view and cross-sectional views, respectively, of a transistor comprising a plurality of newly grown channel regions, according to illustrative embodiments;

FIGS. 1i, 1j and 1k schematically illustrate a top view and cross-sectional views, respectively, of the transistor comprising a plurality of newly grown channel regions with “hexagonal” cross-sectional shape, according to illustrative embodiments;

FIGS. 1l, 1m and 1n schematically illustrate a top view and cross-sectional views, respectively, of the transistor comprising a plurality of newly grown channel regions with oval cross-sectional shape, according to illustrative embodiments;

FIGS. 1o, 1p and 1 q schematically illustrate a top view and cross-sectional views, respectively, of the transistor in a further advanced manufacturing stage, according to illustrative embodiments;

FIGS. 2a-2m schematically illustrate top views and cross-sectional views, respectively, of a semiconductor device during various manufacturing stages in forming a three-dimensional transistor on the basis of a non-masked epitaxial growth of channel regions in combination with a replacement gate approach, according to illustrative embodiments;

FIG. 3 schematically illustrates a top view of the semiconductor device, in which disposable semiconductor fins may be provided in a self-aligned manner, according to further illustrative embodiments; and

FIGS. 4a-4i schematically illustrate a top view and cross-sectional views, respectively, of a semiconductor device, in which disposable semiconductor fins may be provided in a late manufacturing stage upon performing a replacement gate approach, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The following embodiments are described in sufficient detail to enable those skilled in the art to make and use the invention. It is to be understood that other embodiments would be evident based on the present disclosure, and that system, structure, process or mechanical changes may be made without departing from the scope of the present disclosure. In the following description, numerous specific details are given to provide a thorough understanding of the disclosure. However, it will be apparent that the embodiments of the disclosure may be practiced without these specific details. In order to avoid obscuring the present disclosure, some well-known circuits, system configurations, structure configurations and process steps are not disclosed in detail.

Generally, the present disclosure contemplates manufacturing techniques and semiconductor devices in which a non-planar transistor configuration, also referred to as a three-dimensional transistor or a FinFET, may be provided on the basis of a process strategy in which initial fins formed from a semiconductor base material, such as silicon, may be used, at least partially, as disposable fins, which are removed at any appropriate manufacturing stage so as to provide a template surface for growing thereon a desired channel semiconductor material, such as a high mobility material, without using a mask material for controlling the lateral growth during the selective epitaxial growth process. To this end, facial growth may be applied, in which the difference in growth behavior with respect to different crystal planes is taken advantage of in order to obtain a self-limiting lateral growth and thus a controlled cross-sectional shape of the resulting channel region. For example, a plurality of deposition recipes are available, in which a crystallographically anisotropic growth behavior is achieved by appropriately adjusting process parameters. It is well known that different crystal planes, such as (111), (110), (100) planes and the like in the case of a cubic face-centered lattice structure, require differently adapted process parameters in order to obtain substantially the same growth rate. On the other hand, process parameters may be selected such that a desired growth rate is obtained for one surface orientation, while a significantly reduced growth rate is established for one or more other surface orientations. Appropriate process parameters may readily be determined on the basis of well-established deposition recipes, possibly in combination with appropriate experiments in order to take into consideration company specific tool resources, since typically the process parameters may have to be adapted to the specific deposition tool and the like.

The deposition behavior of selective epitaxial growth techniques is taken advantage of when forming the channel region of three-dimensional transistors, since the cross-sectional shape, i.e., the cross-section perpendicular to the current flow in the channel region, may be adjusted on the basis of process parameters rather than providing a mask material, as is frequently used in conventional strategies. In this manner, additional process steps associated with the formation and removal of the mask material may be avoided, while at the same time the cross-sectional shape of the newly grown channel regions may be adjusted in accordance with device requirements, for instance in terms of drive current, threshold voltage, an electrostatic channel control and the like, with a high degree of flexibility, which would not be achievable on the basis of conventional masked epitaxial growth techniques.

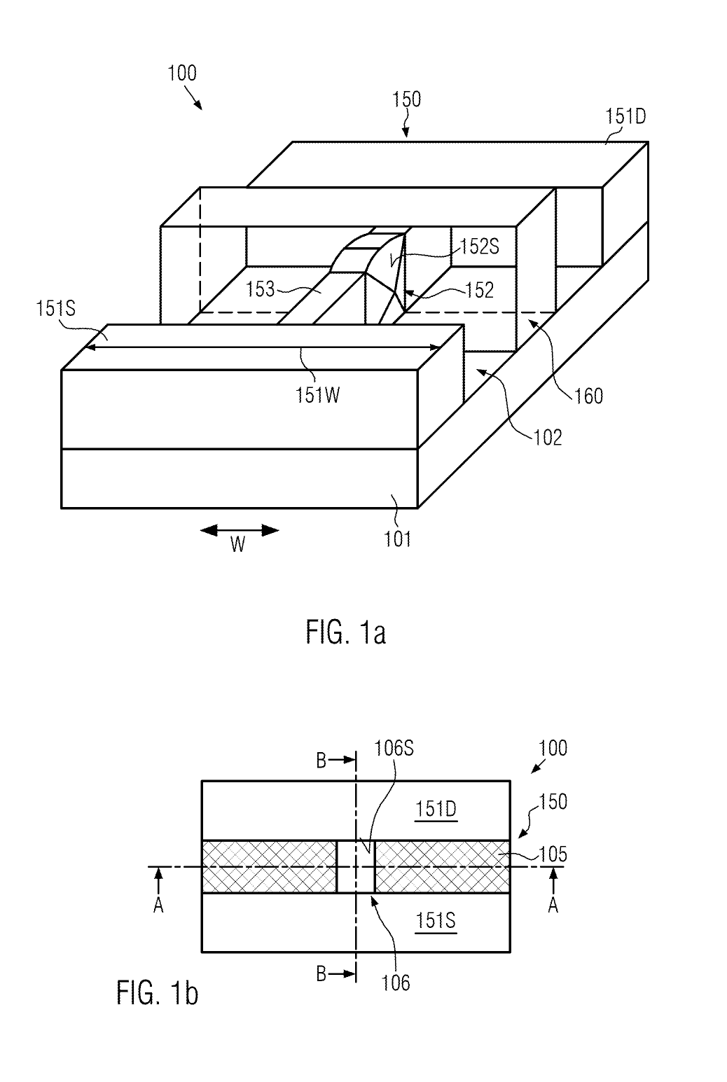

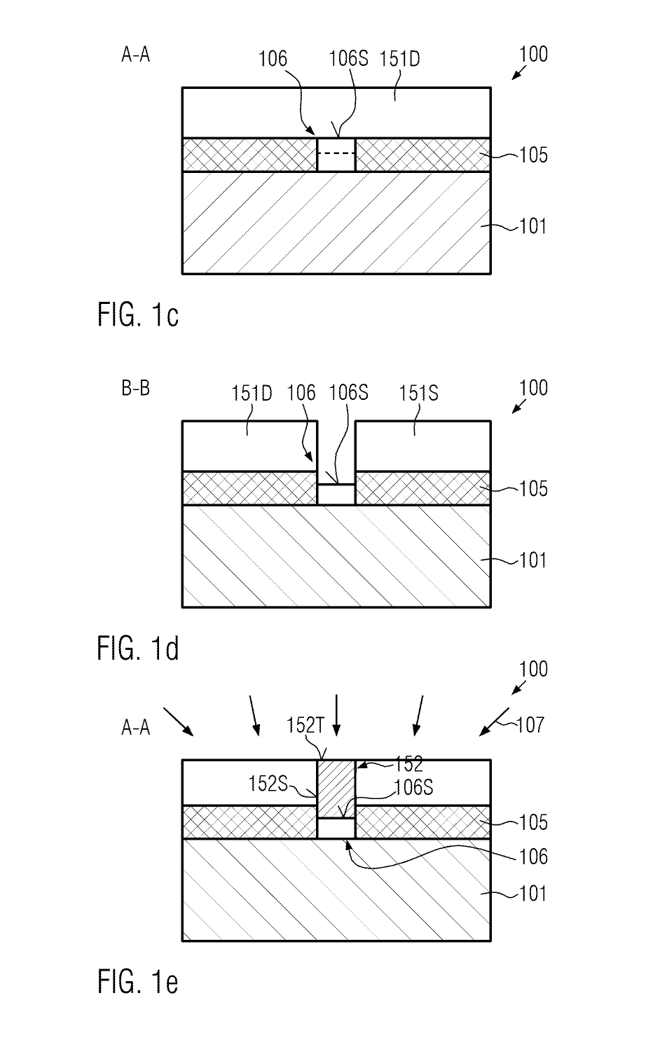

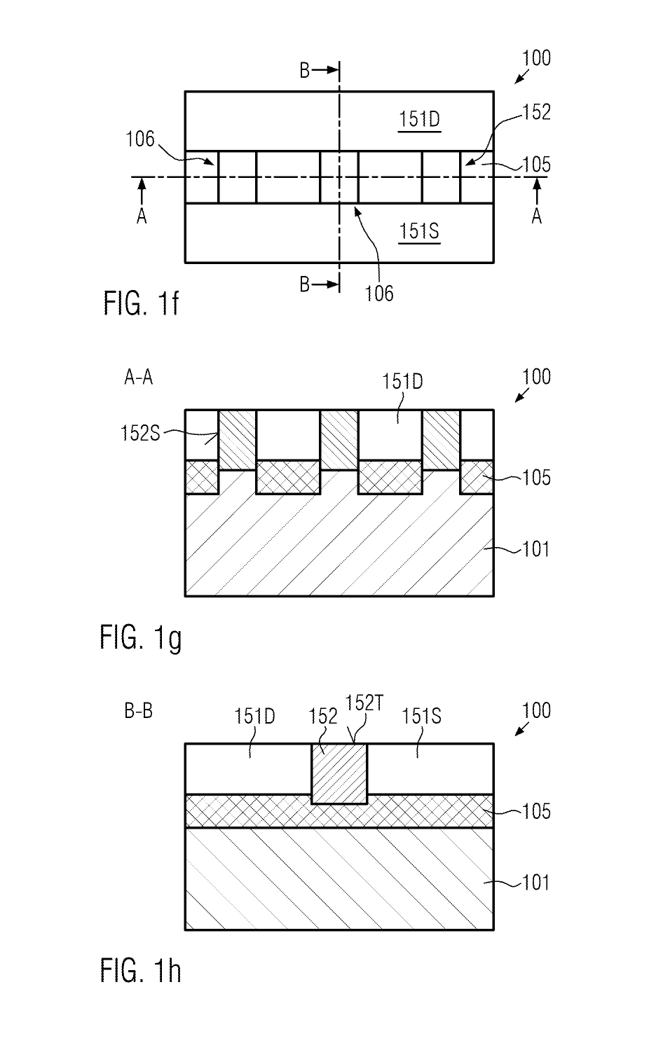

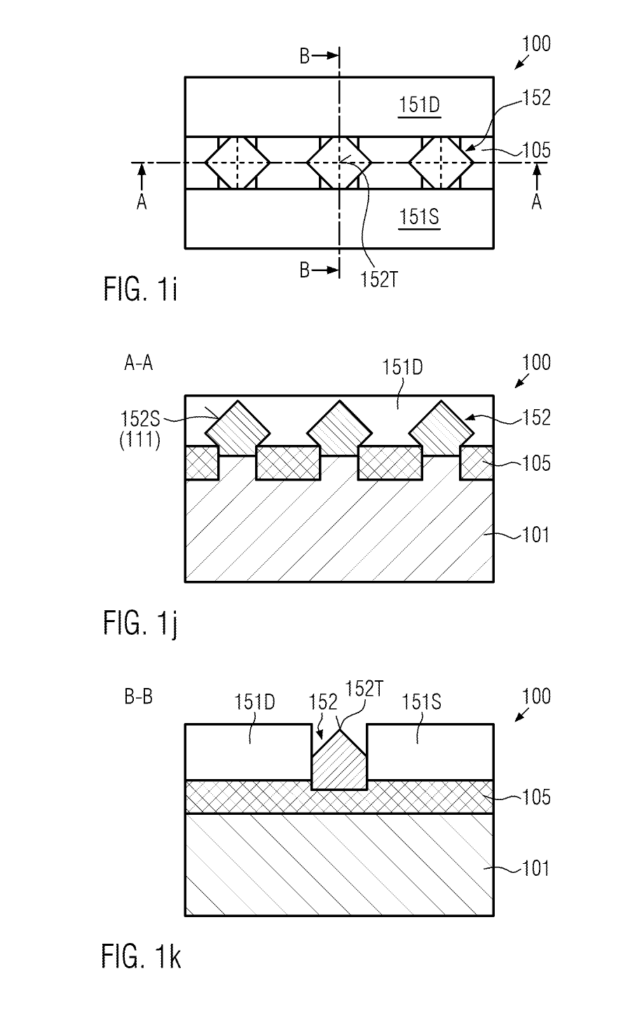

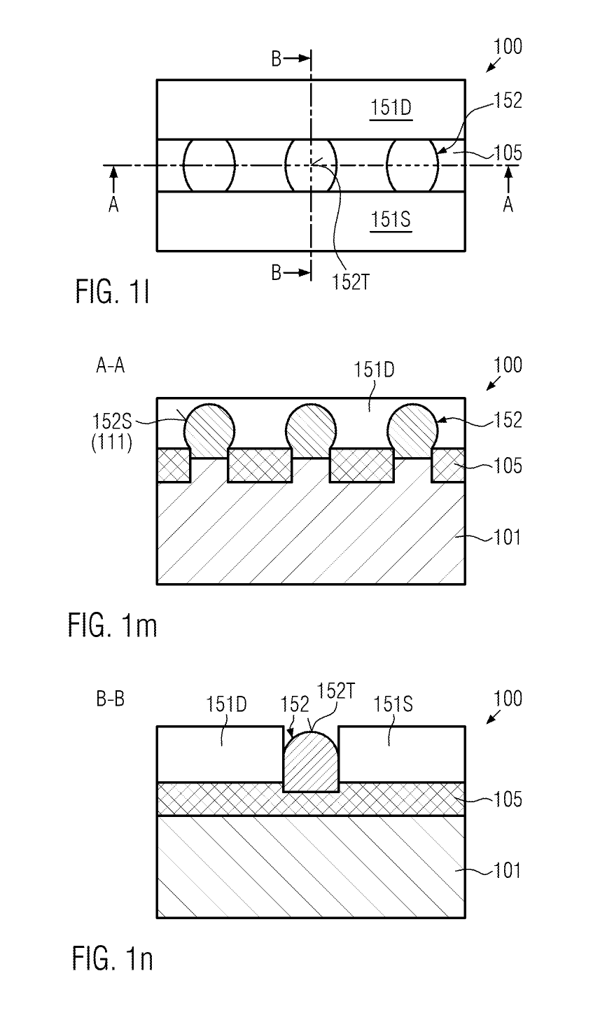

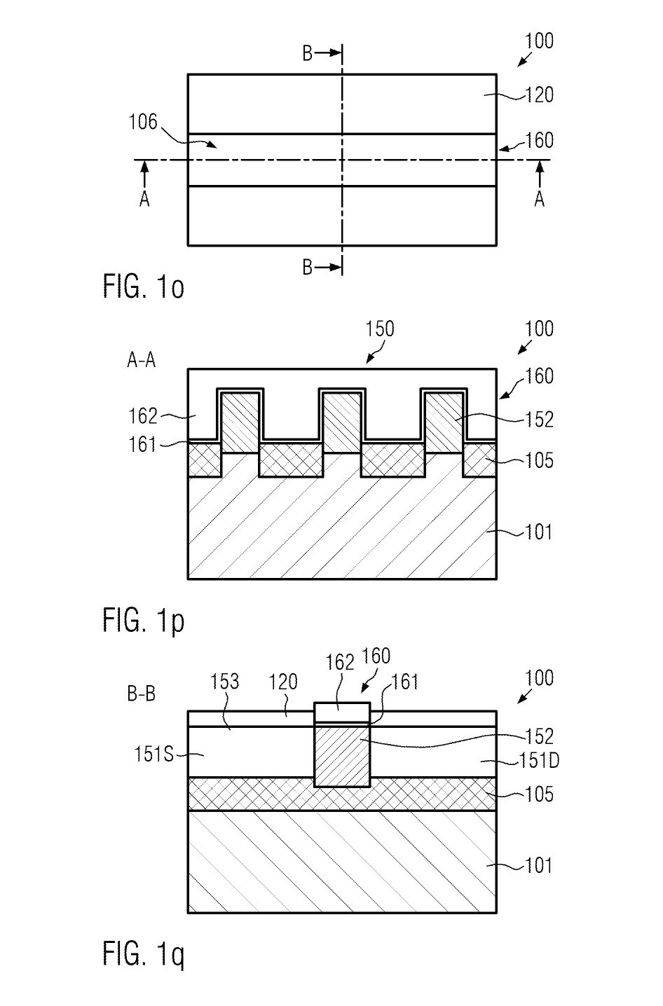

FIG. 1a schematically illustrates a perspective view of a semiconductor device 100 comprising a three-dimensional transistor 150, which is also referred to as a FinFET device. As shown, the semiconductor device 100 may comprise a substrate 101, which may be any appropriate carrier material, such as a crystalline semiconductor material in the form of a silicon material and the like. In other cases, the substrate 101 may include an insulating material (not shown) in order to provide an SOI configuration. Moreover, a semiconductor layer 102, which is also referred to as a semiconductor base material, may be provided with any appropriate characteristics, for instance in the form of a silicon material, a silicon/germanium material and the like. It should be appreciated that the semiconductor base material 102 may be divided into a plurality of active regions, each of which may correspond to one or more three-dimensional transistors. For convenience, the base material 102 is illustrated so as to be patterned into a drain region 151D and a source region 151S, possibly in combination with an initial semiconductor fin 153, which may represent the rest of a disposable fin structure, a portion of which has been replaced by a desired semiconductor material having different characteristics compared to the base material 102, as will be described in more detail later on. Hence, the source and drain regions 151S, 151D may represent appropriately doped and dimensioned portions of the base material 102 with a width 151W, which is also referred to as a drain and source width, extending along a width direction W of the transistor 150.

Thus, in the embodiment shown in FIG. 1a, the fin 153 may be understood as a portion of the source region 151S and the drain region 151D, respectively, in order to connect to a channel region 152 having an appropriate cross-sectional shape and being formed from a desired semiconductor material, such as a semiconductor material having a greater charge carrier mobility compared to the base material 102, at least for one type of charge carriers. In other illustrative embodiments, as will be described later on, the channel region 152 may directly connect to the drain and source regions 151D, 151S without an intermediate end portion 153. It should be appreciated that the channel region 152 may have appropriately shaped surface areas 152S, such as sidewall faces and the like, which may have been formed on the basis of controlling process parameters of a selective epitaxial growth process, as already discussed above, in order to avoid the provision of a disposable mask material and to enable enhanced flexibility for adjusting the cross-sectional shape of the channel region 152 in view of taking into consideration certain requirements of the transistor 150, such as superior electrostatic control of the channel region 152, increased drive current, appropriately adjusted threshold voltage and the like.

Furthermore, in the manufacturing stage shown, a gate electrode structure 160 is formed above and around the channel region 152 and may comprise an appropriate gate dielectric material, such as a conventional dielectric material, a high-k dielectric material or any combination thereof, in combination with an appropriate electrode material, such as polysilicon, a metal-containing electrode material, possibly in combination with appropriate work function metals and the like. For convenience, these materials are not shown in FIG. 1a. Furthermore, the gate electrode structure 160 may comprise a spacer structure (not shown) of any appropriate configuration, which may typically be formed so as to cover the fin portions 153.

The geometric configuration of the device 100 may be formed on the basis of any appropriate process strategy, wherein, however, contrary to conventional approaches, the channel region 152 is formed on the basis of selective epitaxial growth techniques without restricting the lateral growth by a mask material. Rather, the control of process parameters is used so as to obtain a desired configuration of the surface areas 152S in accordance with the overall device requirements.

With reference to the further drawings, several process strategies will now be described in more detail, in which the basic configuration of the transistor 150 may be formed on the basis of disposable fin portions provided on the basis of a semiconductor base material, which may act as an appropriate template surface for growing thereon a desired semiconductor material. The disposable fin portions or fins may be formed in an early manufacturing stage, in a late manufacturing stage, based on conventional gate electrode structures or on the basis of highly sophisticated high-k metal gate electrode structures, and the like, as will be discussed later on.

FIG. 1b schematically illustrates a top view of the transistor 150 in an early manufacturing stage, in which the drain and source regions 151D, 151S may be provided so as to be connected by a template surface 106S, which may represent a top surface of a disposable fin formed from the semiconductor base material. Furthermore, the template surface 106S may be laterally embedded by an insulating material 105, such as a silicon dioxide material, silicon nitride material and the like. It should be appreciated that the line A-A represents the transistor width direction, while the line B-B represents the transistor length direction.

FIG. 1 c schematically illustrates a cross-sectional view of the device 100 along the section A-A in FIG. 1b. That is, the cross-sectional view of FIG. 1c may correspond to a section along the transistor width direction, as discussed above. As shown, the insulating material 105 may be formed above the substrate 101 and may have embedded therein the rest of a disposable fin 106, whose top surface 106S represents the template surface to be used as a growth surface for forming thereon a desired semiconductor material in order to provide a channel region of desired characteristics. It should be appreciated that an initial height of the fin portion 106 typically corresponds to the height of the drain and source regions 151D (as shown in the figure), 151S.

The configuration of the device 100 as shown in FIG. 1 c may be formed on the basis of any appropriate process strategy, for instance, as will be discussed later on. Typically, the template surface 106S may be formed by etching the initial semiconductor fin 106 by any appropriate etch process, wherein process parameters, such as etch time for a given removal rate, may be controlled such that the height of the template surface 106S may be appropriately set. For example, the surface 106S may not necessarily be on the same height level as the surface of the silicon material 105, but may be recessed to a certain degree, as indicated by the broken line, if considered appropriate. In other cases, the template surface 106S may be positioned above the insulating material 105.

FIG. 1 d schematically illustrates a cross-sectional view along the line B-B of FIG. 1b, i.e., this section may illustrate a section along the transistor length direction at a lateral position that corresponds to a section through the semiconductor fin 106. As shown, the template surface 106S is recessed with respect to the drain and source regions 151D, 151S as to enable the formation of a desired channel semiconductor material on the surface 106S in order to provide a connection between the drain and source regions 151D, 151S with superior charge carrier mobility and with a desired cross-sectional shape, as discussed above.

FIG. 1 e schematically illustrates the device 100 according to a cross-sectional view A-A in a further advanced manufacturing stage. As illustrated, the device 100 may be exposed to a selective deposition ambient during a process 107, in which a desired semiconductor material is selectively grown on the template surface 106S in the absence of any lateral disposable mask material. As discussed above, the selective epitaxial growth process 107 may be controlled such that a lateral restriction of the growth rate may be accomplished on the basis of process parameters by taking advantage of the different growth behavior for different crystal planes. For example, the template surface 106S may represent the (100) plane of the semiconductor base material, such as a silicon material, wherein the process parameters, such as temperature, gas flow rates of reactive gases, such as hydrogen, chlorine containing gases and the like, pressure, or other parameters, may be selected so as to obtain significant deposition on (100) planes only, while a deposition on other crystal planes, such as (110) planes, may be suppressed. Therefore, upon growing material on the (100) plane, which thus represents a top surface 152T of the channel region 152, deposition on the sidewalls 152S of the growing channel region 152, which may represent (110) planes, may be efficiently suppressed, thereby substantially preserving the lateral dimensions of the template surface 106S and forming the channel region 152 so as to have a substantially rectangular cross-sectional shape. It should be appreciated that an appropriate set of parameters may be readily determined on the basis of experiments for a desired semiconductor material to be used for the channel region 152. For example, silicon/germanium, germanium, GaAs, InP, and the like are well-established semiconductor materials for which selective epitaxial growth recipes are available. Starting from these recipes, appropriate parameters may be established, in order to control the lateral growth of the material 152, thereby adjusting a desired cross-sectional shape of the channel region 152. Consequently, in addition to selecting an appropriate semiconductor material for the channel region 152 and incorporating a desired dopant species therein, if required, a further degree of freedom for adjusting the overall transistor characteristics is provided by the option of controlling the cross-sectional shape during the process 107. For example, the electrical field distribution in the channel region 152 may be controlled on the basis of the geometry of the channel region 152, in combination of other characteristics, thereby enabling a specific tuning of the dynamic and static behavior of the channel region 152 upon completing the three-dimensional transistor structure.

FIGS. 1 f, 1g and 1h schematically illustrate a top view and cross-sectional views, respectively, in the manufacturing stage, which corresponds to the manufacturing stage as shown in FIG. 1 e, wherein a plurality of channel regions 152 may be provided so as to connect to the drain and source regions 151D, 151S. It should be appreciated that, in a three-dimensional transistor, typically a plurality of non-planar channel regions may be used so as to increase overall current drive capability for given lateral dimensions of a transistor. In this example, three channel regions 152 are illustrated, which may have sidewall surfaces 152S so as to substantially define a rectangular cross-sectional shape perpendicular to the current flow direction (FIG. 1g), as, for instance, discussed above with reference to FIG. 1 e. Consequently, in this example, process parameters may be used during the selective epitaxial growth process such that significant material deposition is achieved for a crystal plane that corresponds to the template surface 106S (FIG. 1e).

FIGS. 1i, 1j and 1k schematically illustrate a top view and cross-sectional views, respectively, wherein the plurality of channel regions 152 may be provided on the basis of epitaxial growth techniques, in which lateral growth of the semiconductor material under consideration may be restricted by controlling process parameters such that significant deposition on (111) planes may be suppressed. Also in this case, respective process parameters may be readily determined on the basis of well-established deposition recipes and/or on the basis of corresponding experiments. Hence, as shown in FIG. 1j, the sidewalls 152S may substantially represent (111) planes, thereby forming a “hexagonal” configuration. Similarly, the top surface 152T may be represented as the vertex of corresponding (111) planes of the semiconductor material under consideration. Consequently, a more complex configuration of the cross-sectional shape of the channel regions 152 is obtained, which may be taken advantage of for adjusting electrostatic control and/or threshold voltage and/or current drive capability. For example, the hexagonal architecture may allow superior charge carrier depletion within the channel regions 152 for a given overall cross-sectional area compared to a pure rectangular design thereby possibly allowing increased overall drive current capability.

FIGS. 1l, 1m and 1n schematically illustrate a top view and cross-sectional views, respectively, wherein the plurality of channel regions 152 may be provided on the basis of epitaxial growth techniques in which lateral growth of the semiconductor material under consideration may be restricted by controlling process parameters such that a certain degree of deposition may also be obtained on crystal planes that do not coincide with the template surface, however, to a lesser degree. Also in this case, respective process parameters may be readily determined on the basis of well-established deposition recipes and/or on the basis of corresponding experiments. Hence, as shown, the sidewalls 152S and the top surfaces 152T may form an “oval” configuration. Consequently, also in this case, a more complex configuration of the cross-sectional shape of the channel regions 152 is obtained, which may be taken advantage of when adjusting the desired transistor characteristics.

FIGS. 1o, 1p and 1q schematically illustrate a top view and cross-sectional views, respectively, of the device 100 in a further advanced manufacturing stage. As shown, the device 100 may comprise the gate electrode structure 160, which may at least be laterally embedded in an interlayer dielectric material 120, such as a silicon dioxide material, silicon nitride material and the like. As shown in the cross-sectional views of FIGS. 1p and 1q, the gate electrode structure 160 may comprise a gate dielectric material 161, which may be provided in the form of a conventional dielectric material, such as silicon dioxide, silicon nitride, silicon oxynitride and the like, with an appropriate thickness so as to comply with the overall requirements of the transistor 150. In other cases, the gate dielectric material 161 may comprise a high-k dielectric material, possibly in combination with a conventional dielectric material, if a direct contact of a high-k dielectric material with the semiconductor material of the channel regions 152 is considered inappropriate. Moreover, the gate electrode structure 160 may comprise one or more electrode materials 162, such as a polysilicon material, a silicon/germanium material, other high mobility semiconductor materials and the like, depending on the overall process strategy. In other cases, one or more additional metal-containing materials may be provided, for instance in the form of a metal/semiconductor compound, a pure metal layer and the like, in order to increase overall conductivity of the gate electrode structure 160.

Consequently, the gate electrode structure 160 may be provided in the form of a conventional electrode structure including well-established materials, such as silicon dioxide, silicon nitride or any combination thereof, in combination with well-established electrode materials, such as polysilicon, silicon/germanium and the like, whose conductivity may be enhanced by providing a silicide and the like. In other cases, other high mobility semiconductor materials may be used instead of polysilicon, as considered appropriate. In still other illustrative embodiments, the gate electrode structure 160 may be provided in the form of a sophisticated high-k metal gate electrode structure, which may be provided on the basis of any appropriate manufacturing strategy, including approaches based on a replacement gate technology, as will be described later on. In other cases, the gate electrode structure 160, irrespective of its configuration, may be formed after completing the channel regions 152 and prior to establishing the final configuration of the drain and source regions 151D, 151S.

For example, the drain and source regions 151D, 151S may be formed so as to incorporate any appropriate dopant species, for instance based on implantation techniques, after forming the gate electrode structure 160, which may have appropriate spacer elements (not shown) in order to enable a desired lateral and vertical dopant profile, as is for instance also known from a conventional planar transistor architecture. In this case, also additional mechanisms may be implemented for increasing overall conductivity of the drain and source regions 151D, 151S, such as incorporating a metal silicide 153 and/or incorporating a strain-inducing mechanism (not shown), if a further modification of the charge carrier mobility in the channel regions 152 is considered appropriate on the basis of respective strain conditions.

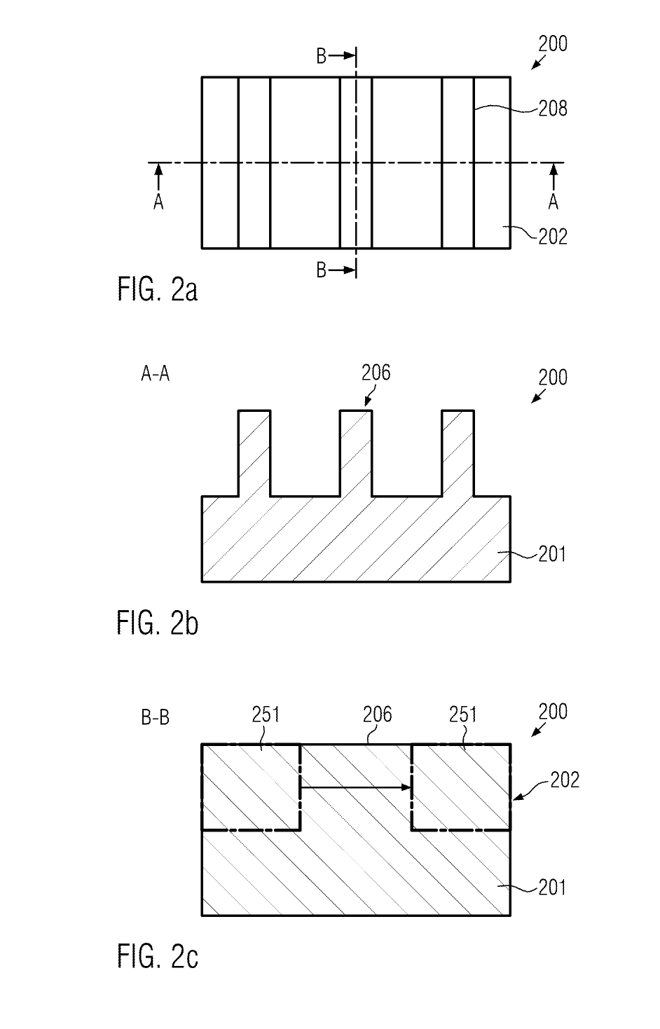

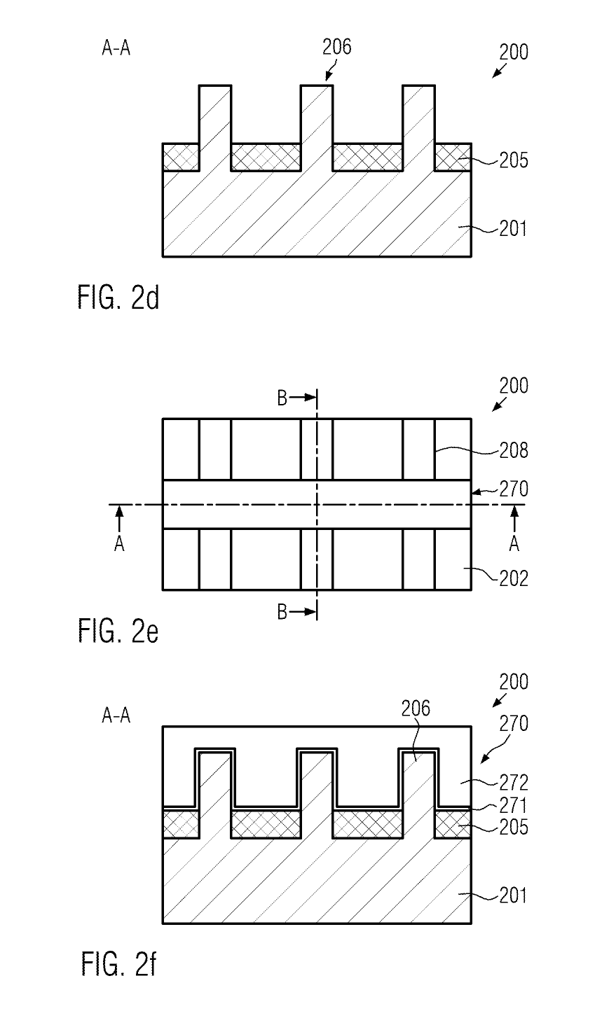

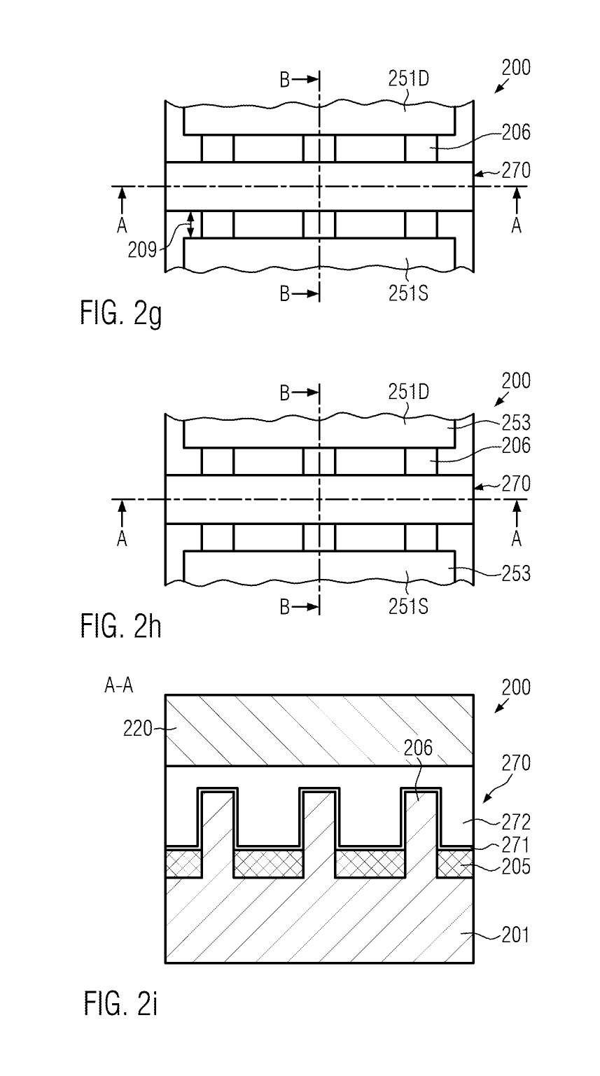

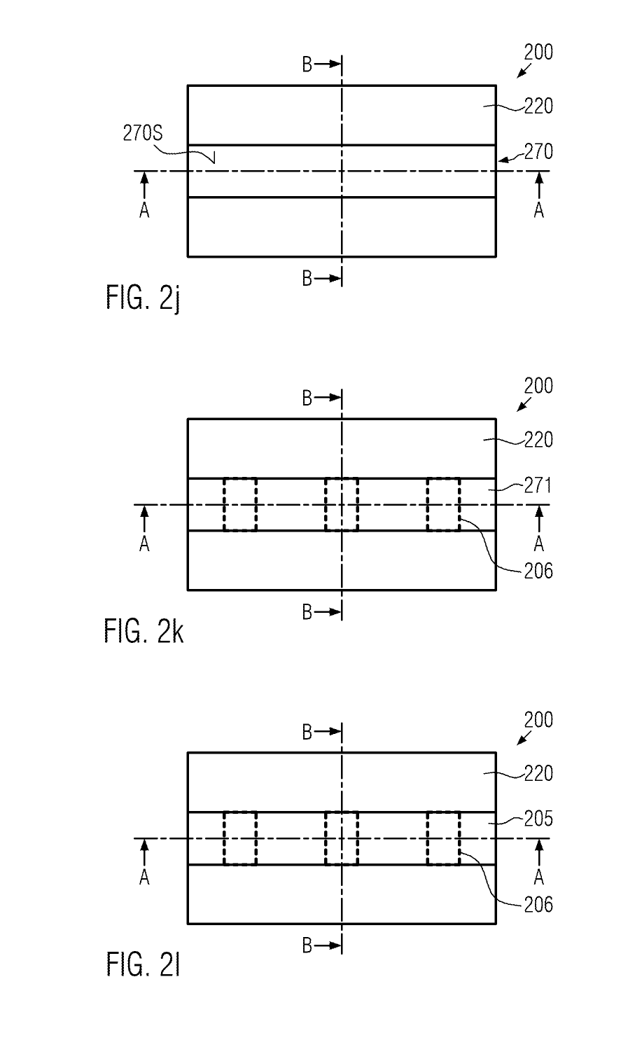

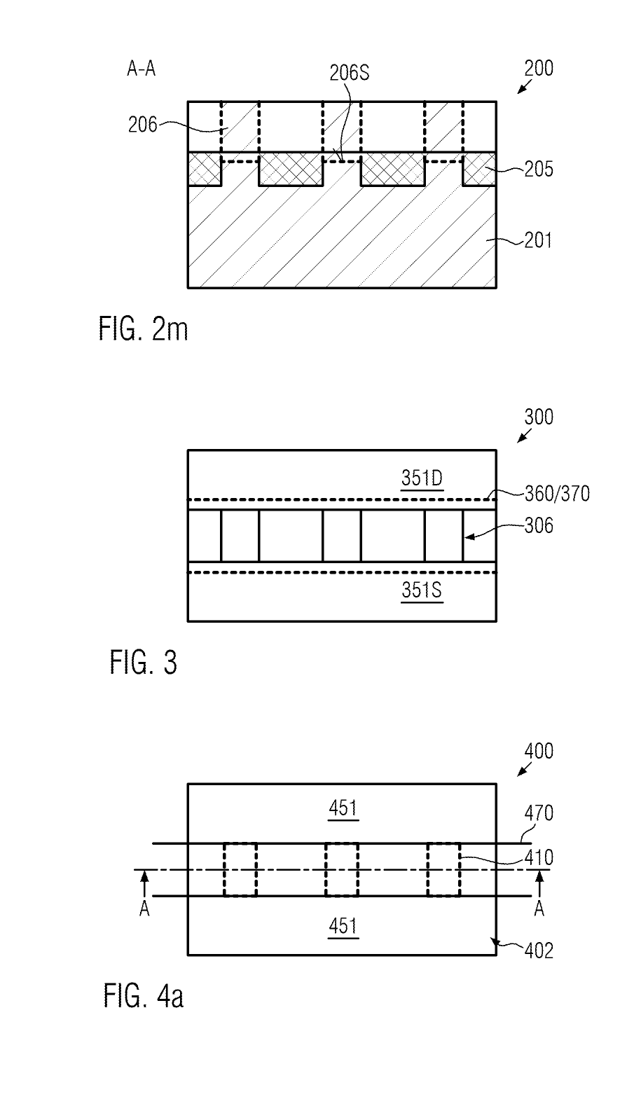

With reference to FIGS. 2a-2m, manufacturing strategies will now be described in which initial semiconductor fins may be formed in an early manufacturing stage by patterning the semiconductor base material, while the final length of the disposable semiconductor fins may be adjusted on the basis of an epitaxial growth for forming continuous drain and source regions on the basis of a placeholder gate electrode structure.

FIG. 2a schematically illustrates a top view of a semiconductor device 200 in an early manufacturing stage, in which an etch mask 208 may be provided so as to define the lateral size, position and shape of initial semiconductor fins to be formed from the semiconductor base material 202.

FIG. 2b schematically illustrates a cross-sectional view A-A after a corresponding etch process in order to form disposable fins 206 from the semiconductor base material 202. In the example shown, the fins 206 extend down to a substrate 201, which may also represent a crystalline part of the base material 202 or which may comprise an insulating material (not shown), if an SOI configuration is considered.

FIG. 2c schematically illustrates a cross-sectional view B-B, in which end portions 251 of the initial fins 206 indicate the area of drain and source regions still to be formed on the basis of an epitaxial growth process so as to merge the respective end portions 251.

FIG. 2d schematically illustrates a cross-sectional view A-A of the device 200 in a further advanced manufacturing stage, in which an insulating material 205 may be formed so as to laterally enclose lower portions of the semiconductor fins 206, thereby defining an effective geometrical height of the fins 206 for the further processing. The material 205 may be provided in the form of silicon dioxide, silicon nitride and the like, depending on the overall process strategy. The material 205 may be deposited by using any appropriate deposition technique, thereby forming the material 205 laterally adjacent to and above the semiconductor fins 206. Thereafter, a planarization process may be applied so as to obtain a substantially planar surface topography, on the basis of which a further removal process, such as an etch process, may be applied in order to remove a portion of the material 205, thereby finally adjusting a thickness of the material 205 and thus a geometrically effective height of the fins 206. To this end, any well-established etch techniques, such as plasma-based etch recipes, wet chemical etch recipes, may be applied, in which a high degree of selectivity of the semiconductor base material with respect to the insulating material 205 is taken advantage of.

FIGS. 2e and 2f schematically illustrate a top view and a cross-sectional view A-A, respectively, in a further advanced manufacturing stage, in which a replacement gate structure 270 may be provided. As shown, the structure 270 may comprise a dielectric material 271, such as silicon dioxide and the like, which may typically act as an etch stop material in a later manufacturing stage, in combination with a placeholder material 272, which may be replaced in a later manufacturing stage on the basis of well-established etch strategies. Frequently, polysilicon is used as the material 272, since well-established deposition, planarization and etch techniques are available for this material. It should be appreciated, however, that any other appropriate placeholder material may be used in the structure 270. Hence, the materials 271, 272 may be deposited on the basis of well-established techniques, followed by a planarization process, such as chemical mechanical planarization (CMP), in order to provide appropriate surface conditions for a subsequent patterning process based on sophisticated lithography and etch techniques. After the patterning of the placeholder structure 270, typically a spacer structure may be formed around the structure 270, which, however, for convenience is not shown in the drawings. To this end, silicon dioxide, silicon nitride and the like may be used as an appropriate material for forming the corresponding spacer structure.

FIG. 2g schematically illustrates a top view of the device 270 in a further advanced manufacturing stage. As shown, a drain region 251D and a source region 251S are formed from end portions of the fins 206, as, for instance, indicated with reference to FIG. 2c. To this end, a selective epitaxial growth process may be applied so as to form semiconductor material preferably between the end portions of the fins 206, thereby obtaining a continuous semiconductor region. During the selective epitaxial growth process, the structure 270 in combination with a spacer structure 209, which is illustrated to be transparent for convenience, act as a growth mask. In this manner, an appropriate offset between the structure 270 and the resulting drain and source regions may be obtained on the basis of the spacer structure 209. It should be appreciated that any further processes may be applied so as to obtain the desired configuration of the drain and source regions. For example, dopant species may be incorporated during the selective epitaxial growth process, while in other cases, additionally or alternatively, dopant species may also be incorporated by implantation processes in combination with appropriate masking regimes. Thereafter, high temperature anneal processes may be applied by using any appropriate technique in order to activate dopant and reduce implantation-induced lattice damage, thereby also obtaining the final vertical and lateral dopant profile of the drain and source regions.

FIG. 2h schematically illustrates a top view of the device 200 in a further advanced manufacturing stage, in which a metal silicide 253 may be formed in the drain and source regions 251D, 251S, while the structure 270 and the structure 209 may act as a mask. To this end, any well-established silicidation technique may be applied.

FIG. 2i schematically illustrates a cross-sectional view A-A in a further advanced manufacturing stage, in which an interlayer dielectric material 220 may be formed above and laterally adjacent to the placeholder structure 270, thereby also covering and thus passivating the drain and source regions previously formed. For example, the interlayer dielectric material 220 may be provided in the form of one or more dielectric layers, such as a silicon dioxide material, a silicon nitride material and the like, in accordance with the overall device requirements. To this end, well-established deposition techniques are available. Thereafter, appropriate planarization processes may be applied so as to remove an excess portion of the material 220 in order to finally expose the top surface of the placeholder structure 270. To this end, CMP techniques, etch processes and the like may be applied.

FIG. 2j schematically illustrates a top view of the device 200 after exposing a top surface 270S of the placeholder structure 270 in order to prepare the device for the replacement of the structure 270 with an actual sophisticated high-K metal gate electrode structure.

FIG. 2k schematically illustrates a top view of the device 200 after the removal of the placeholder material 272 (FIG. 2f), thereby exposing the material 271, which may act as an etch stop material during the removal of the material 272. To this end, a plurality of highly selective etch recipes are available for removing well-established placeholder materials, such as polysilicon, selectively with respect to dielectric materials, such as silicon dioxide, silicon nitride and the like.

FIG. 2l schematically illustrates a top view of the semiconductor device 200 after the removal of the material layer 271 (FIG. 2k) on the basis of any well-established etch recipes, such as a wet chemical cleaning process and the like, as are well-established in the art. Hence, after the corresponding removal process, the dialectic layer 205 and the top surface of a central portion of the semiconductor fins 206 may be exposed.

FIG. 2m schematically illustrates the device 200 during an anisotropic etch process for removing material of the semiconductor fins 206, thereby finally creating a template surface 206S at an appropriate height level, as is, for instance, also discussed above with reference to the semiconductor device 100. The material removal of the central portion of the fins 206 (disposable fins) may be accomplished on the basis of a selective anisotropic etch recipe, as are typically well established in the art, for removing silicon material selectively with respect to silicon dioxide, silicon nitride and the like.

In this manufacturing stage, a similar process strategy may be applied, as previously discussed with reference to FIGS. 1b-1q, in order to form a desired semiconductor material on the template surfaces 206S by using a non-masked selective epitaxial growth technique, as described above. Hence, any desired semiconductor material, in particular a high mobility semiconductor material, may be grown with a desired cross-sectional shape, wherein the shape may be controlled on the basis of process parameters without employing any laterally provided mask material. After forming the corresponding channel regions on the basis of the template surfaces 206S, the further processing may be continued by forming the actual gate electrode structure, for instance, by depositing a gate dielectric material, such as a high-k material, in combination with one or more appropriate electrode materials, in order to provide a sophisticated high-k metal gate electrode structure. Thus, a similar configuration may be obtained as shown in FIG. 1a, wherein the respective channel regions may have any appropriate cross-sectional shape and the gate electrode structure may have a desired configuration, for instance in terms of a high-k material and a highly conductive electrode metal.

With reference to FIG. 3, a further process strategy will be described, in which self-aligned disposable semiconductor fins may be provided together with drain and source regions.

FIG. 3 schematically illustrates a top view of a semiconductor device 300, in which drain and source regions 351D, 351S may be formed together with disposable semiconductor fins 306 by appropriately patterning the semiconductor base material using appropriate patterning strategies. That is, a corresponding mask material may be provided above the semiconductor base material so as to define the position, size and shape of an electrode structure 360/370, wherein a further mask may be provided so as to define the position and size of the semiconductor fins 306. Consequently, based on these masks, the drain and source regions 351D, 351S may be formed so as to be connected to the semiconductor fins 306, without requiring any additional processes for forming continuous drain and source regions on the basis of end portions of respective semiconductor fins. That is, in this case, end portions of the semiconductor fins 306 may connect to the drain and source regions, which in turn define the size and position of the electrode structure 360/370. Hence, on the basis of the configuration shown, after the removal of the mask for defining the size and position of the semiconductor fins 306, these semiconductor fins may be reduced in height, as is already discussed above. Prior to or after etching the semiconductor fins 306, an insulating material, such as silicon dioxide, may be filled into the spaces between the semiconductor fins 306, which may be accomplished by deposition, planarization and etch techniques, as is also discussed above. Thereafter, the desired semiconductor material may be grown on the respective template surfaces, i.e., respective top surfaces of the semiconductor fins 306, while the lateral growth may be controlled, as discussed above. Thereafter, the structure 360 may be formed so as to represent the actual gate electrode structure, while, in other cases, the structure 370 may be provided in the form of a placeholder structure, wherein the actual gate electrode structure may be provided in a later manufacturing stage on the basis of a replacement gate approach, as also discussed above.

In other illustrative embodiments, the semiconductor fins 306 may be etched so as to reduce the height and form a corresponding top surface as a template surface, as already discussed above, and thereafter the placeholder structure 370 may be formed prior to reflowing corresponding channel regions. In this case, the further processing may be continued by completing the basic transistor configuration using the placeholder structure 370 as a mask, as already discussed above. After providing an interlayer dielectric material, the placeholder structure 370 may be removed, as discussed above, thereby again exposing the template surfaces, which may now be used for redrawing a desired semiconductor material so as to form the channel regions of the device 300 with appropriate cross-sectional shape, as already discussed above. In this case, the drain and source regions 351D, 351S may be formed so as to be compatible with the corresponding process temperatures that are required during the selective epitaxial growth process for forming the channel regions. For example, a metal silicide material in the drain and source regions 351D, 351S may be formed in a later manufacturing stage, i.e., upon or after forming the actual gate electrode structure. Thus, after growing the desired channel regions, the further processing may be continued by depositing appropriate materials for the gate electrode structure 360, which may be provided in the form of a sophisticated high-k metal gate electrode structure.

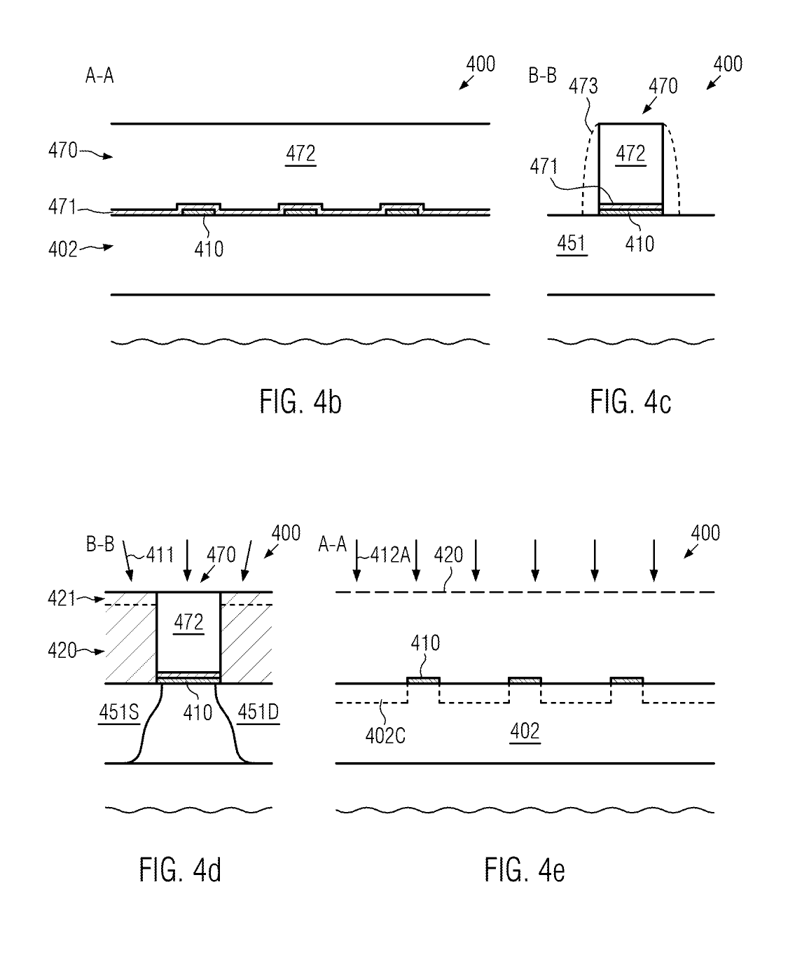

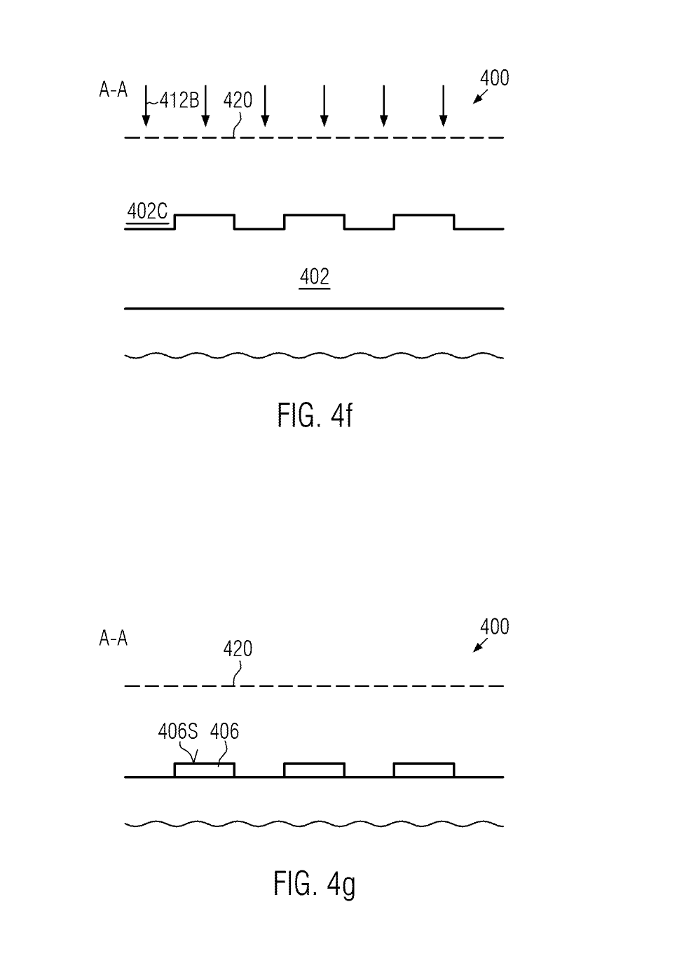

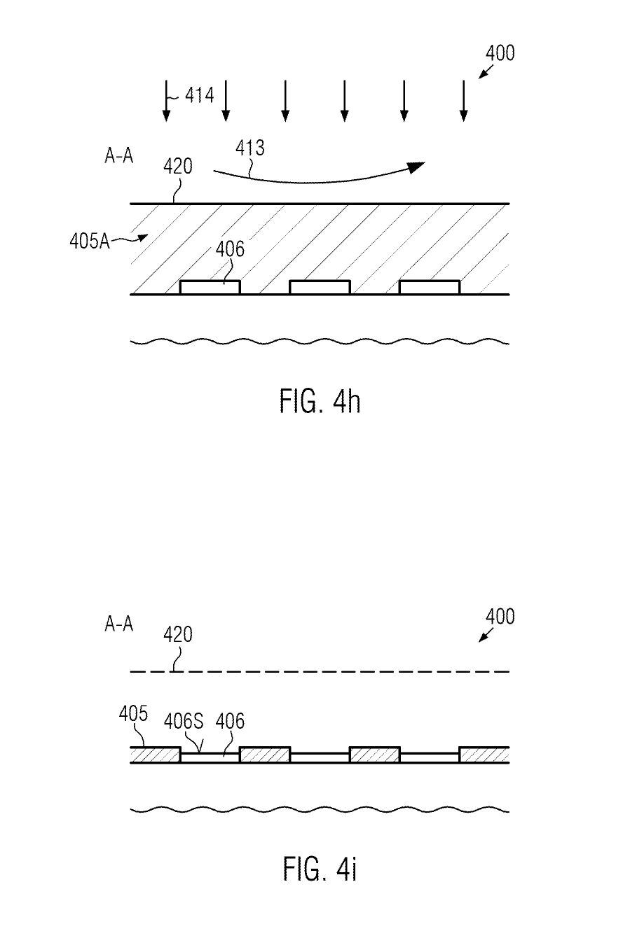

With reference to FIGS. 4a-4i, further illustrative embodiments will now be described, in which the disposable semiconductor fins may be formed in a late manufacturing stage, i.e., during a replacement gate approach.

FIG. 4a schematically illustrates a top view of a semiconductor device 400 in a manufacturing stage in which drain and source areas 451 may be provided in a self-aligned manner with respect to a placeholder gate electrode structure 470. Furthermore, a buried mask 410 may define the size and position of disposable semiconductor fins still to be formed. That is, the drain and source areas 451 are still connected regions of a semiconductor base material 402, wherein a central part thereof is covered by the placeholder structure 470 comprising the buried mask 410.

FIG. 4b schematically illustrates a cross-sectional view A-A of the device 400 in a manufacturing stage corresponding to the stage as shown in FIG. 4a. As illustrated, the placeholder structure 470 may comprise a dielectric material 471, such as silicon dioxide and the like, and a placeholder material 472, such as polysilicon and the like. Furthermore, the mask 410 may be provided, for instance in the form of any appropriate mask material, such as silicon nitride and the like.

FIG. 4c schematically illustrates a cross-sectional view B-B of the device 400, showing that the placeholder structure 470 is formed above the base material and the mask 410, wherein possibly a spacer structure 473 may be provided on sidewalls of the structure 470 in order to comply with the overall requirements for forming the drain and source regions 451, for instance based on implantation processes and the like.

The semiconductor device 400 as shown may be formed on the basis of any appropriate process strategy, in which the mask 410 may be formed on the basis of sophisticated deposition, lithography and patterning strategies, followed by a process sequence for forming the structure 470, also including sophisticated lithography and etch techniques. Thereafter, any further processes may be performed so as to incorporate dopant species into the drain and source areas 451, while also other mechanisms may be implemented, such as strain-inducing mechanisms and the like.

FIG. 4d schematically illustrates a cross-sectional view B-B of the device 400 in a further advanced manufacturing stage. As illustrated, a drain region 451D and a source region 451S are provided so as to have a desired lateral and vertical dopant profile, which may be established on the basis of the placeholder structure 470, as discussed above. Furthermore, an interlayer dielectric material 420 may be provided so as to passivate the transistor structure. The interlayer dielectric material 420 may have any appropriate configuration, for instance one or more material layers may be provided, such as an appropriate cap layer 421 in order to impart superior etch resistivity to the material 420, and the like. Appropriate materials may be silicon dioxide, silicon nitride, silicon oxynitride and the like. The material 420 may be formed on the basis of deposition techniques, followed by appropriate planarization processes in order to expose a top surface of the placeholder structure 470, as is also previously discussed. Based on this device configuration, a removal process 411 may be applied, in which the structure 470 may be removed, which may be accomplished on the basis of process techniques, as discussed above. During this process, the mask 410 may reliably protect the underlying semiconductor base material between the drain and source regions 451D, 451S.

FIG. 4e schematically illustrates a cross-sectional view A-A of the device 400 during a further material removal process 412A, in which a portion of the base material 402 may be removed in the presence of the mask 410, thereby forming respective recesses 402C. In this manner, a certain degree of etch lag of the material 402 covered by the mask 410 may be obtained upon removal of the mask 410 and performing a further etch process so as to form the corresponding template surfaces for a subsequent regrowth of a desired channel material.

In other illustrative embodiments, the etch process 412A is continued so as to form respective semiconductor fins by increasing the depth of the recesses 402C as required by the overall device configuration.

FIG. 4f schematically illustrates the semiconductor device 400 in cross-sectional view A-A in a further advanced manufacturing stage, in which the recesses 402C are formed in the base material 402 and the mask 410 (FIG. 4e) is removed. In a further etch step 412B, material of the semiconductor base material 402 may be removed, thereby substantially preserving the initially created surface topography.

FIG. 4g schematically illustrates the device 400 after a desired portion of the semiconductor base material 402 (FIG. 4f) has been removed. Hence, a semiconductor fin 406 including a template surface 406S may be provided. It should be appreciated that removing an appropriate portion of the semiconductor base material 402 may include embodiments in which the base material may be removed down to a buried insulating material (not shown) if an SOI configuration is considered, while, in other cases, the etch process may be stopped at any appropriate depth within the semiconductor base material. Consequently, the semiconductor fins 406 and thus the corresponding template surfaces 406S are provided within a gate opening defined by the surrounding interlayer dielectric material 420, without requiring additional masking steps during the replacement gate approach.

FIG. 4h schematically illustrates the device 400 in cross-sectional view A-A in a further advanced manufacturing stage, in which a dielectric material 405A may be provided, for instance by any appropriate deposition technique, followed by a planarization process 413, in which a substantially planar surface topography may be obtained. In this stage, an etch process 414 may be applied so as to remove a significant portion of the dielectric material 405A.

FIG. 4i schematically illustrates the device 400 in cross-sectional view A-A in a further advanced manufacturing stage. As shown, the dielectric material 405A has been removed to such a degree that a desired insulating material 405 may be provided between the semiconductor fins 406 and thus the template surfaces 406S. To this end, the etch process 414 (FIG. 4h) may be appropriately controlled so as to stop at a desired height level. Furthermore, the etch process 414 may be highly selective with respect to the interlayer dielectric material 420, which may be accomplished by providing an appropriate cap layer, as discussed above, or by applying an appropriate surface treatment thereon prior to actually removing the placeholder gate electrode structure 470 (FIG. 4d). For example, a nitration process may be applied so as to impart superior etch resistivity to the material 420 with respect to the etch process 414.

On the basis of the configuration as shown in FIG. 4i, the further processing may be continued by growing a desired semiconductor material on the template surfaces 406S by using a process strategy as discussed above. Hence, channel regions may be formed with a desired cross-sectional shape and with a desired semiconductor material, for instance a high mobility material, so as to provide superior transistor characteristics.

As a result, the present disclosure provides manufacturing techniques and semiconductor devices in which dimensional transistors in bulk architecture and SOI architecture may be implemented in a highly efficient manner on the basis of well-established process technology, for instance silicon technology, while nevertheless channel regions of the three-dimensional transistors may be formed on the basis of any desired semiconductor material, for instance high mobility semiconductor materials, while also appropriate cross-sectional shapes may be obtained. To this end, the epitaxial growth process is carried out without a lateral masking material, wherein the lateral growth and thus the finally obtained sidewall configuration and thus cross-sectional shape may be controlled on the basis of process parameters, thereby significantly reducing overall process complexity compared to conventional strategies, in which the mask material is required, while at the same time superior flexibility in designing the characteristics of the channel region is achieved. The non-masked selective epitaxial growth may be combined with replacement gate approaches, conventional gate fabrication strategies, with self-aligned provision of the initial disposable semiconductor fins, or with strategies in which continuous drain and source regions may be formed by epitaxial growth techniques.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a fin from a semiconductor base material in an active region of a semiconductor device, said fin terminating at one side in a drain region of said active region, said fin terminating at the other side in a source region;
removing at least a portion of said fin so as to provide a crystalline template surface, said crystalline template surface having lateral dimensions determined by said fin; and
forming a channel region on said crystalline template surface so as to connect to said drain and source regions by forming a semiconductor material in a selective epitaxial growth without restricting a lateral growth of said semiconductor material by a mask material.

2. The method of claim 1, wherein forming said semiconductor material comprises forming a semiconductor material having a charge carrier mobility that is higher than a charge carrier mobility of said semiconductor base material for at least one type of charge carriers.

3. The method of claim 1, wherein forming said fin comprises etching into said semiconductor base material so as to form said fin with an initial length, masking a central portion of said fin and epitaxially growing a further semiconductor material around non-masked end portions of said fin having said initial length.

4. The method of claim 1, wherein forming said fin comprises forming a mask above said semiconductor base material so as to cover an area corresponding to said drain and source regions and said fin and removing a non-covered portion of said semiconductor base material.

5. The method of claim 1, wherein forming said fin comprises forming a mask above said semiconductor base material so as to define a width of said fin, forming said drain and source regions in the presence of said mask and forming said fin after said drain and source regions.

6. The method of claim 1, wherein forming said channel region comprises using a crystallographically anisotropic deposition recipe.

7. The method of claim 1, further comprising forming a placeholder gate electrode structure above said active region and replacing said placeholder gate electrode structure after forming said drain and source regions.

8. The method of claim 7, wherein said fin is formed prior to forming said placeholder gate electrode structure.

9. The method of claim 7, wherein said fin is formed after removal of said placeholder gate electrode structure.

10. The method of claim 1, further comprising forming an insulating material adjacent to a lower portion of said fin so as to adjust a geometrically effective height of said fin.

11. A method of forming a semiconductor device, the method comprising:
forming a crystalline template surface in a semiconductor base material, said crystalline template surface being located laterally between a drain region and a source region;
forming a channel region on said crystalline template surface by growing a semiconductor material while controlling a lateral growth rate by using a crystallographically anisotropic deposition recipe; and
forming a gate dielectric material and an electrode material of a gate electrode structure on at least a portion of said channel region.

12. The method of claim 11, wherein forming said crystalline template surface comprises forming a semiconductor fin from said semiconductor base material in an active region and removing at least a portion of said semiconductor fin after removal of a placeholder gate electrode structure.

13. The method of claim 12, wherein said semiconductor fin is formed prior to forming said drain and source regions.

14. The method of claim 11, wherein forming said crystalline template surface comprises forming a placeholder gate electrode structure above said semiconductor base material in an active region and removing a portion of said semiconductor base material after removal of said placeholder gate electrode structure.

15. The method of claim 14, wherein removing a portion of said semiconductor base material comprises forming a hard mask layer above said semiconductor base material prior to forming said placeholder gate electrode structure.

16. The method of claim 11, wherein forming said channel region comprises performing a selective epitaxial growth process without using a mask material for restricting a lateral material growth along at least a portion of a height of said channel region.

17. The method of claim 16, wherein performing said selective epitaxial growth process comprises forming a semiconductor material having an increased charge carrier mobility compared to said semiconductor base material for at least one type of charge carriers.

18. A semiconductor device, comprising:
a drain region and a source region formed in a semiconductor base material of said semiconductor device, said drain region and said source region having a drain and source width along a width direction;
a channel region formed from a semiconductor material other than said semiconductor base material and extending between said drain region and said source region, said channel region having a width along said width direction that is less than said drain and source width, said width of said channel region varying along a height direction; and
a gate electrode structure formed on sidewalls of said channel region and above said top surface.

19. The semiconductor device of claim 18, wherein sidewalls of one side of said channel region are inclined and form an angle that is substantially defined by lattice planes of said semiconductor material.

20. The semiconductor device of claim 18, wherein a shape of said channel region is a substantially oval shape when viewed in top view.
